(19) United States
(12) Patent Application Publication
(10) Pub. No.: US 2026/0130146 A1
(43) Pub. Date: May 7, 2026

(54) SUBSTRATE PROCESSING METHOD AND SUBSTRATE PROCESSING APPARATUS

(71) Applicant: Tokyo Electron Limited, Tokyo (JP)

(72) Inventors: Reiko ABE, Koshi City (JP); Yuta HAMASHIMA, Koshi City (JP)

(73) Assignee: Tokyo Electron Limited, Tokyo (JP)

(21) Appl. No.: 19/378,373

(22) Filed: Nov. 4, 2025

(30) Foreign Application Priority Data
Nov. 5, 2024 (JP) 2024-193788

(51) Int. Cl. H01L 21/311; H01L 21/67

(52) U.S. Cl. CPC H10P 50/283; H10P 72/0426; H10P 72/0604

(57) ABSTRACT

A substrate processing method includes generating an etching liquid by adding a silicic acid compound to an alkaline processing liquid, and etching a polysilicon film formed on a substrate with the etching liquid.

### CROSS-REFERENCE TO RELATED APPLICATION

This application claims the benefit of Japanese Patent Application No. 2024-193788 filed on Nov. 5, 2024, the entire disclosures of which are incorporated herein by reference.

### TECHNICAL FIELD

The various aspects and embodiments described herein pertain generally to a substrate processing method and a substrate processing apparatus.

### BACKGROUND

Conventionally, there is known a technique of etching a polysilicon film formed on a substrate by using an alkaline processing liquid (see Patent Document 1).

Patent Document 1: International Publication No. 2022-041076

### SUMMARY

In an exemplary embodiment, a substrate processing method includes generating an etching liquid by adding a silicic acid compound to an alkaline processing liquid; and etching a polysilicon film formed on a substrate with the etching liquid.

### BRIEF DESCRIPTION OF THE DRAWINGS

FIG. 1 is a schematic block diagram illustrating a configuration of a substrate processing system according to an exemplary embodiment;

FIG. 2 is an enlarged cross sectional view illustrating an example surface structure of a wafer according to the exemplary embodiment;

FIG. 3 is a schematic block diagram illustrating a configuration of an etching apparatus according to the exemplary embodiment;

FIG. 4 is a flowchart illustrating an example sequence of a control processing performed by the substrate processing system;

FIG. 5 is a diagram illustrating an example variation in a concentration of a silicic acid compound in a processing vessel during an etching processing according to the exemplary embodiment;

FIG. 6 is a diagram showing a relationship between the concentration of the silicic acid compound added to an etching liquid and a BT ratio;

FIG. 7 is a diagram showing another example variation in the concentration of the silicic acid compound in the processing tub during the etching processing according to the exemplary embodiment;

FIG. 8 is a diagram showing yet another example variation in the concentration of the silicic acid compound in the processing tub during the etching processing according to the exemplary embodiment;

FIG. 9 is a diagram showing still yet another example variation in the concentration of the silicic acid compound in the processing tub during the etching processing according to the exemplary embodiment;

FIG. 10 is a diagram showing still yet another example variation in the concentration of the silicic acid compound in the processing tub during the etching processing according to the exemplary embodiment; and

FIG. 11 is a flowchart illustrating another example sequence of the control processing performed by the substrate processing system according to the exemplary embodiment.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, exemplary embodiments of a substrate processing method and a substrate processing apparatus according to the present disclosure will be described in detail with reference to the accompanying drawings. The present disclosure is not limited to the exemplary embodiments to be described below. Further, it should be noted that the drawings are schematic and relations in sizes of individual components and ratios of the individual components may sometimes be different from actual values. Even between the drawings, there may exist parts having different dimensional relationships or different ratios.

Conventionally, there is known a technique of etching a polysilicon film formed on a substrate by using an alkaline processing liquid. In this conventional technique, however, there may be a significantly large difference between an etching amount of the polysilicon film at an opening side of a hole formed in the substrate and an etching amount of the polysilicon film at a bottom side of the hole.

Therefore, there has been a demand for a technique capable of overcoming the aforementioned problem and improving the uniformity of the etching processing of the polysilicon film formed on the substrate, for example, enhancing the uniformity of the etching amount in the depth direction of the hole formed in the substrate.

### Configuration of Substrate Processing System

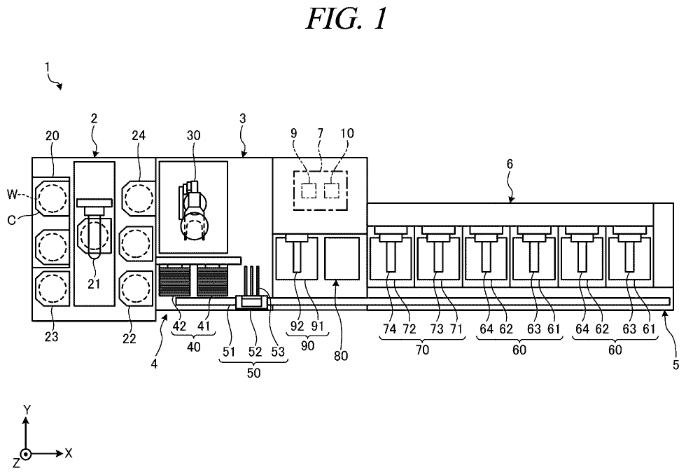

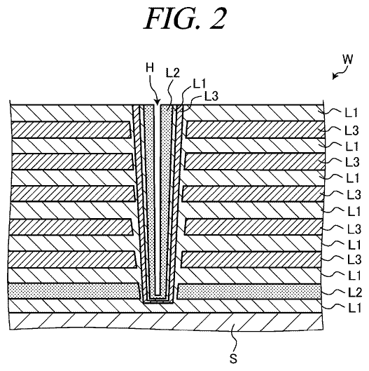

First, a configuration of a substrate processing system 1 according to an exemplary embodiment will be explained with reference to FIG. 1 and FIG. 2. FIG. 1 is a schematic block diagram illustrating the configuration of the substrate processing system 1 according to the exemplary embodiment. The substrate processing system 1 is an example of a substrate processing apparatus.

As depicted in FIG. 1, the substrate processing system 1 according to the exemplary embodiment includes a carrier carry-in/out module 2, a lot formation module 3, a lot placement module 4, a lot transfer module 5, a lot processing module 6, and a control device 7.

The carrier carry-in/out module 2 includes a carrier stage 20, a carrier transfer mechanism 21, carrier stocks 22 and 23, and a carrier placement table 24.

The carrier stage 20 places thereon multiple carriers C transferred from the outside. The carrier C is a container that accommodates a plurality of (e.g., 25 sheets of) wafers W stacked vertically, while holding each wafer W in a horizontal posture. The carrier transfer mechanism 21 transfers the carriers C between the carrier stage 20, the carrier stocks 22 and 23, and the carrier placement table 24.

Here, a structure of the wafer W to be subjected to an etching processing in the substrate processing system 1 according to the exemplary embodiment will be explained with reference to FIG. 2. FIG. 2 is an enlarged cross sectional view illustrating an example surface structure of the wafer W according to the exemplary embodiment. The wafer W is an example of a substrate.

As shown in FIG. 2, the wafer W to be subjected to the etching processing in the substrate processing system 1 (see FIG. 1) according to the exemplary embodiment has a substrate S, a silicon oxide film L1, a polysilicon film L2, and a silicon nitride film L3.

In the wafer W according to the exemplary embodiment, a single layer of silicon oxide film L1 is located on a surface of the wafer W, which is made of silicon or the like. Furthermore, a single layer of polysilicon film L2 is located on a surface of this silicon oxide film L1.

Also, multiple silicon oxide films L1 and multiple silicon nitride films L3 are stacked alternately in multiple layers on a surface of this polysilicon film L2. In addition, a hole H is provided in a stacked body of the silicon oxide films L1, the polysilicon film L2, and the silicon nitride films L3 described above. The hole H is an example of a recess.

On an inner surface of this hole H, the silicon oxide film L1, the silicon nitride film L3, the silicon oxide film L1, and the polysilicon film L2 are stacked in this order. That is, when the wafer W is processed in the substrate processing system 1, the polysilicon film L2 is exposed on the inner surface of the hole H.

In the etching processing according to the exemplary embodiment, a portion of the polysilicon film L2 located on the inner surface of the hole H is etched.

Referring back to FIG. 1, a plurality of wafers W yet to be processed are transferred from the carrier C placed on the carrier placement table 24 to the lot processing module 6 by a substrate transfer mechanism 30 to be described later. Also, a plurality of processed wafers W are transferred from the lot processing module 6 to the carrier C placed on the carrier placement table 24 by the substrate transfer mechanism 30.

The lot formation module 3 includes the substrate transfer mechanism 30, and forms a lot. The lot is composed of multiple (e.g., 50 sheets of) wafers W to be processed simultaneously, which is a combination of the wafers W stored in one or multiple carriers C.

The multiple wafers W forming the one lot are arranged at a regular distance therebetween with their plate surfaces facing each other. In the present disclosure, the one lot is not limited to consisting of the multiple wafers W, and a single wafer W may constitute the single lot.

The substrate transfer mechanism 30 transfers the multiple wafers W between the carrier C placed on the carrier placement table 24 and the lot placement module 4.

The lot placement module 4 has a lot transfer table 40, on which the lot transferred between the lot formation module 3 and the lot processing module 6 by the lot transfer module 5 are temporarily placed (put on standby). The lot transfer table 40 includes a placement table 41 on which the lot formed in the lot formation module 3 and yet to be processed is placed, and a placement table 42 on which the lot processed in the lot processing module 6 is placed. The multiple wafers W belonging to the one lot are placed on each of the placement tables 41 and 42, while being arranged in a front-to-back direction in an upright posture.

The lot transfer module 5 has a lot transfer mechanism 50, and transfers the lot between the lot placement module 4 and the lot processing module 6 and, also, within the lot processing module 6. The lot transfer mechanism 50 is equipped with a rail 51, a mover 52, and a substrate holder 53.

The rail 51 is positioned along the X-axis, spanning the lot placement module 4 and the lot processing module 6. The mover 52 is configured to be movable along the rail 51 while holding the multiple wafers W. The substrate holder 53 is located on the mover 52 and holds the multiple wafers W arranged in the front-to-back direction in the upright posture.

The lot processing module 6 performs an etching processing, a cleaning processing, a drying processing, and the like on the multiple wafers W belonging to the one lot. In the lot processing module 6, two etching apparatuses 60, a cleaning apparatus 70, a cleaning apparatus 80, and a drying apparatus 90 are arranged along the rail 51.

The etching apparatus 60 performs an etching processing on the multiple wafers W of the one lot collectively. The cleaning apparatus 70 performs a cleaning processing on the multiple wafers W of the one lot collectively. The cleaning apparatus 80 performs a cleaning processing on the substrate holder 53. The drying apparatus 90 performs a drying processing on the multiple wafers W of the one lot collectively. Further, the number of each of the etching apparatus 60, the cleaning apparatus 70, the cleaning apparatus 80, and the drying apparatus 90 is not limited to the example shown in FIG. 1.

The etching apparatus 60 includes a processing tub 61 for etching, a processing tub 62 for rinsing, and substrate elevating mechanisms 63 and 64.

The processing tub 61 is capable of accommodating the wafers W of the one lot that are arranged in an upright posture, and stores therein a chemical liquid for etching (hereinafter, also referred to as “etching liquid”). Details of this processing tub 61 will be described later.

The processing tub 62 stores therein a processing liquid for rinsing (e.g., ionized water). The substrate elevating mechanisms 63 and 64 hold the multiple wafers W that forms the lot, while arranging them in the front-to-back direction in the upright posture.

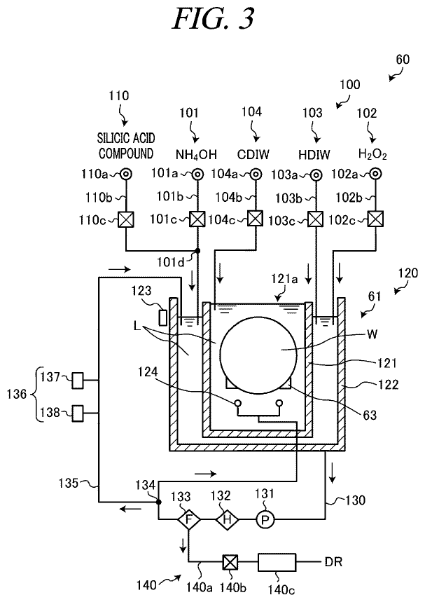

The etching apparatus 60 holds the lot transferred by the lot transfer module 5, using the substrate elevating mechanism 63, and immerses the lot in an etching liquid L (see FIG. 3) in the processing tub 61, thereby performing an etching processing.

The lot subjected to the etching processing in the processing tub 61 is transferred to the processing tub 62 by the lot transfer module 5. The etching apparatus 60 then holds the transferred lot by using the substrate elevating mechanism 64, and immerses the lot in a rinsing liquid in the processing tub 62, thereby performing a rinsing processing. The lot subjected to the rinsing processing in the processing tub 62 is transferred by the lot transfer module 5 to a processing tub 71 of the cleaning apparatus 70.

The cleaning apparatus 70 is equipped with the processing tub 71 for cleaning, a processing tub 72 for rinsing, and substrate elevating mechanisms 73 and 74. The processing tub 71 for cleaning stores therein a chemical liquid for cleaning.

The processing tub 72 for rinsing stores therein a processing liquid for rinsing (e.g., ionized water). The substrate elevating mechanisms 73 and 74 hold the multiple wafers W belonging to the one lot, while arranging them in the front-to-back direction in the upright posture.

The cleaning apparatus 70 holds the lot transferred by the lot transfer module 5, using the substrate elevating mechanism 73, and immerses the lot in a cleaning liquid in the processing tub 71, thereby performing a cleaning processing. The lot subjected to the cleaning processing in the processing tub 71 is transferred to the processing tub 72 by the lot transfer module 5.

The cleaning apparatus 70 holds the lot transferred from the processing tub 71, using the substrate elevating mechanism 74, and immerses the lot in a rinsing liquid in the processing tub 72, thereby performing a rinsing processing. The lot subjected to the rinsing processing in the processing tub 72 is transferred to a processing tub 91 of the drying apparatus 90 by the lot transfer module 5.

The drying apparatus 90 includes the processing tub 91 and a substrate elevating mechanism 92. A process gas for drying is supplied to the processing tub 91. The substrate elevating mechanism 92 holds the wafers W of the one lot, while arranging them in the front-to-back direction in the upright posture.

The drying apparatus 90 holds the lot transferred by the lot transfer module 5, using the substrate elevating mechanism 92, and performs a drying processing by using the processing gas for drying supplied into the processing tub 91. The lot subjected to the drying processing in the processing tub 91 is then transferred by the lot transfer module 5 to the lot placement module 4.

The cleaning apparatus 80 supplies a processing liquid for cleaning and a drying gas to the substrate holder 53 of the lot transfer mechanism 50, thereby performing a cleaning processing of the substrate holders 53.

Also, the substrate processing system 1 is equipped with the control device 7. The control device 7 is, by way of non-limiting example, a computer, and includes circuitry such as a controller 9 and a storage 10. The storage 10 stores therein a program that controls various kinds of processes performed in the substrate processing system 1. The controller 9 controls an operation of the substrate processing system 1 by reading and executing the program stored in the storage 10.

In addition, the program may have been stored on a computer-readable recording medium, and may be installed from that recording medium into the storage 10 of the control device 7. The computer-readable recording medium may include, by way of non-limiting example, a hard disk (HD), a flexible disk (FD), a compact disk (CD), a magneto-optical disk (MO), a memory card, a storage circuit, and so forth.

### Configuration of Etching Apparatus

Now, a configuration of the etching apparatus 60 that performs the etching processing of the wafer W will be explained with reference to FIG. 3. FIG. 3 is a schematic block diagram illustrating the configuration of the etching apparatus 60 according to the exemplary embodiment.

The etching apparatus 60 includes a processing liquid supply 100, a silicic acid supply 110, and a substrate processing device 120. The processing liquid supply 100 supplies an alkaline processing liquid, which is a source material of the etching liquid L, to the substrate processing device 120.

The following exemplary embodiment will be described for an example where SC1, which is a mixture of aqueous ammonia and aqueous hydrogen peroxide, is used as an example of the alkaline processing liquid. However, the alkaline processing liquid in the present disclosure is not limited to the SC1.

The processing liquid supply 100 includes an aqueous ammonia supply 101, an aqueous hydrogen peroxide supply 102, a high-temperature deionized water (HDIW) supply 103, and a cold deionized water (CDIW) supply 104.

The aqueous ammonia supply 101 includes an aqueous ammonia source 101a, an aqueous ammonia supply path 101b, and a flow rate regulator 101c.

The aqueous ammonia source 101a is, for example, a tank that stores aqueous ammonia (an aqueous solution of ammonia; NH₄OH). The aqueous ammonia supply path 101b connects the aqueous ammonia source 101a to an outer tub 122 of the processing tub 61, and supplies the aqueous ammonia from the aqueous ammonia source 101a to the outer tub 122.

The flow rate regulator 101c is located in the aqueous ammonia supply path 101b, and serves to regulate the flow rate of the aqueous ammonia supplied to the outer tub 122. The flow rate regulator 101c includes an opening/closing valve, a flow rate control valve, a flowmeter, and so forth.

The aqueous hydrogen peroxide supply 102 includes an aqueous hydrogen peroxide source 102a, an aqueous hydrogen peroxide supply path 102b, and a flow rate regulator 102c.

The aqueous hydrogen peroxide source 102a is, for example, a tank that stores aqueous hydrogen peroxide (an aqueous solution of hydrogen peroxide; H₂O₂). The aqueous hydrogen peroxide supply path 102b connects the aqueous hydrogen peroxide source 102a to the outer tub 122, and supplies the aqueous hydrogen peroxide from the aqueous hydrogen peroxide source 102a to the outer tub 122.

The flow rate regulator 102c is located in the aqueous hydrogen peroxide supply path 102b, and serves to adjust the flow rate of the aqueous hydrogen peroxide supplied to the outer tub 122. The flow rate regulator 102c includes an opening/closing valve, a flow rate control valve, a flowmeter, and so forth.

The HDIW supply 103 supplies high-temperature deionized water (DIW) to the outer tub 122 to adjust the concentration and the temperature of the etching liquid L stored in the processing tub 61. The HDIW supply 103 includes an HDIW source 103a, an HDIW supply path 103b, and a flow rate regulator 103c.

The HDIW source 103a is, for example, a tank that stores the high-temperature DIW. The HDIW supply path 103b connects the HDIW source 103a to the outer tub 122, and supplies the high-temperature DIW from the HDIW source 103a to the outer tub 122.

The flow rate regulator 103c is located in the HDIW supply path 103b, and serves to adjust the amount of the high-temperature DIW supplied to the outer tub 122. The flow rate regulator 103c includes an opening/closing valve, a flow rate control valve, a flowmeter, and so forth.

By adjusting the supply amount of the high-temperature DIW through the flow rate regulator 103c, the temperature of the etching liquid L, the concentration of the SC1, and the concentration of a silicic acid compound in the etching apparatus 60 are adjusted.

The CDIW supply 104 supplies DIW of a room temperature into an inner tub 121 of the processing tub 61 in order to adjust the concentration and the temperature of the etching liquid L stored in the processing tub 61. The CDIW supply 104 includes a CDIW source 104a, a CDIW supply path 104b, a flow rate regulator 104c, and so forth.

The CDIW source 104a is, for example, a tank that stores the DIW of the room temperature. The CDIW supply path 104b connects the CDIW source 104a to the inner tub 121, and supplies the DIW of the room-temperature from the CDIW source 104a into the inner tub 121.

The flow rate regulator 104c is located in the CDIW supply path 104b, and serves to regulate the amount of the DIW supplied into the inner tub 121. The flow rate regulator 104c includes an opening/closing valve, a flow rate control valve, a flowmeter, and so forth.

By adjusting the supply amount of the DIW of the room temperature through the flow rate regulator 104c, the temperature of the etching liquid L, the concentration of the SC1, and the concentration of the silicic acid compound in the etching apparatus 60 are adjusted.

The silicic acid supply 110 supplies the silicic acid compound, which is a source material of the etching liquid L, to the substrate processing device 120. The silicic acid supply 110 includes a silicic acid source 110a, a silicic acid supply path 110b, and a supply amount regulator 110c.

The silicic acid source 110a is, for example, a tank that stores the silicic acid compound. The silicic acid compound stored in the silicic acid source 110a includes at least one of silicic acid and silicate.

The silicic acid contained in the silicic acid compound in the present exemplary embodiment is, by way of example, colloidal silica. The silicate contained in the silicic acid compound according to the exemplary embodiment is, for example, at least one of sodium silicate, potassium silicate, and calcium silicate.

The silicic acid supply path 110b connects the silicic acid source 110a to a merging point 101d on the aqueous ammonia supply path 101b, and supplies the silicic acid compound from the silicic acid source 110a to the aqueous ammonia supply path 101b.

The supply amount regulator 110c is located in the silicic acid supply path 110b, and serves to adjust the amount of the silicic acid compound supplied to the aqueous ammonia supply path 101b.

In the exemplary embodiment, the silicic acid compound is supplied to the aqueous ammonia supply path 101b to supply the silicic acid compound to the substrate processing device 120 while dissolving it in the aqueous ammonia. Thus, it is possible to suppress silica particles from remaining in pipelines.

Further, the present disclosure is not limited to the case where the silicic acid compound is supplied from the silicic acid source 110a to the processing tub 61 via the aqueous ammonia supply path 101b. By way of example, the present disclosure may also include a case where the silicic acid compound is supplied from the silicic acid source 110a to the processing tub 61 via the HDIW supply path 103b. In this case, the silicic acid compound is supplied to the processing tub 61 while being dissolved in the high-temperature DIW. This also suppresses the silica particles from remaining in pipelines.

Furthermore, the present disclosure may also include a case where the silicic acid compound is supplied directly from the silicic acid source 110a into the outer tub 122. With this configuration, the concentration of the silicic acid compound in the processing tub 61 can be adjusted with high precision.

The substrate processing device 120 immerses the multiple wafers W (i.e., the lot) in the etching liquid L prepared by adding the silicic acid compound to the alkaline processing liquid, thereby performing an etching processing on the multiple wafers W.

The substrate processing device 120 includes the processing tub 61, the substrate elevating mechanism 63, a circulation path 130, and an etching liquid draining device 140. The processing tub 61 includes the inner tub 121, the outer tub 122, and a liquid level sensor 123.

The inner tub 121 is a bath for immersing the multiple wafers W in the etching liquid L, and stores therein the etching liquid L for immersion. The inner tub 121 has an opening 121a at the top, and the etching liquid L is stored up to near this opening 121a.

In the inner tub 121, the multiple wafers W are immersed in the etching liquid L by using the substrate elevating mechanism 63, and the etching processing is performed on the multiple wafers W. The substrate elevating mechanism 63 is configured to be movable up and down, and holds the multiple wafers W vertically, while arranging them in the front-to-back direction.

The outer tub 122 is positioned outside the inner tub 121, surrounding the inner tub 121, and serves to receive the etching liquid L flowing out from the opening 121a of the inner tub 121. As shown in FIG. 3, the liquid level in the outer tub 122 is maintained lower than that in the inner tub 121.

The liquid level sensor 123 measures the height of a liquid surface of the etching liquid L stored in the outer tub 122. The controller 9 (see FIG. 1) according to the exemplary embodiment may measure the amount of the etching liquid L stored in the processing tub 61 based on the height of the liquid surface in the outer tub 122 measured by the liquid level sensor 123.

This is because the inner tub 121 and the circulation path 130 are filled with the etching liquid L, so the liquid amounts therein are always constant. Therefore, by measuring the liquid amount in the outer tub 122 based on the measurement value of the liquid level sensor 123, the total liquid amount in the entire processing tub 61 can be calculated.

The outer tub 122 and inner tub 121 are connected by the circulation path 130. One end of the circulation path 130 is connected to a bottom of the outer tub 122, and the other end of the circulation path 130 is connected to a discharge nozzle 124 located inside the inner tub 121.

The circulation path 130 is provided with a pump 131, a heater 132, a filter 133, and a branch point 134 in this sequence from the outer tub 122 side.

The pump 131 creates a circulating flow of the etching liquid L, which is sent from the outer tub 122 to the inner tub 121 via the circulation path 130. Further, the etching liquid L overflows from the opening 121a of the inner tub 121 and is introduced again into the outer tub 122.

In this way, the circulating flow of the etching liquid L is formed in the substrate processing device 120. That is, this circulating flow is formed in the outer tub 122, the circulation path 130, and the inner tub 121.

The heater 132 adjusts the temperature of the etching liquid L circulating through the circulation path 130. The filter 133 filters the etching liquid L circulating in the circulation path 130.

A branch path 135 is branched off from the branch point 134. This branch path 135 connects the branch point 134 and the outer tub 122. A concentration measurer 136 is located in the branch path 135. The concentration measurer 136 measures the concentrations of components of the etching liquid L stored in the processing tub 61 and flowing through the branch path 135.

The concentration measurer 136 is a circuit that includes, by way of example, concentration sensors 137 and 138. The concentration sensor 137 measures, for example, the concentration of the silicic acid compound among the components of the etching liquid L.

The concentration sensor 138 measures the concentration of, for example, the alkaline processing liquid among the components of the etching liquid L. A signal generated by the concentration measurer 136 is sent to the control device 7 (see FIG. 1).

The etching liquid draining device 140 drains the etching liquid L to a drain DR when replacing all or a portion of the etching liquid L used in the etching processing. The etching liquid draining device 140 has a drain path 140a, a flow rate regulator 140b, and a cooling tank 140c.

The drain path 140a is connected to the circulation path 130. The flow rate regulator 140b is located in the drain path 140a and regulates the amount of the etching liquid L being drained. The flow rate regulator 140b has an opening/closing valve, a flow rate control valve, a flowmeter, and so forth.

The cooling tank 140c temporarily stores and also cools the etching liquid L that has flown through the drain path 140a. In the cooling tank 140c, the draining amount of the etching liquid L is adjusted by the flow rate regulator 140b.

### Exemplary Embodiment

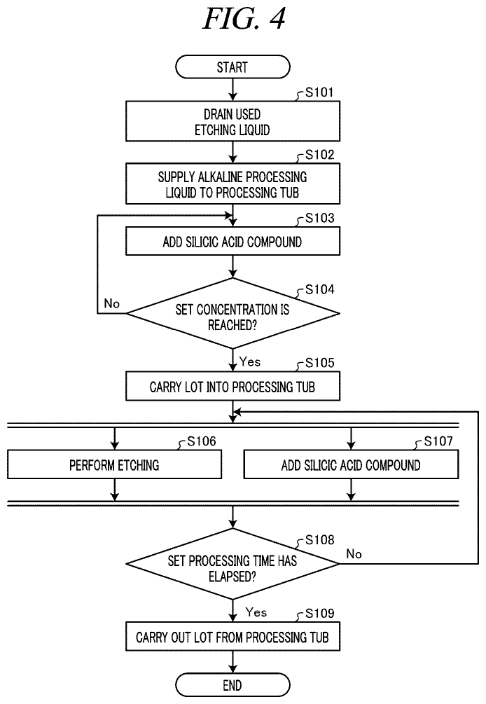

Now, an etching processing according to an exemplary embodiment will be explained in detail with reference to FIG. 4 to FIG. 11. FIG. 4 is a flowchart showing an example of a control processing performed by the substrate processing system 1 according to the exemplary embodiment.

In the control processing according to the exemplary embodiment, the controller 9 first controls the etching liquid draining device 140 and the like to drain the used etching liquid L stored in the processing tub 61 (process S101).

Then, the controller 9 controls the processing liquid supply 100 and the like to supply SC1, which is the alkaline processing liquid, to the processing tub 61 (process S102). For example, in this process S102, the controller 9 supplies the aqueous ammonia, the aqueous hydrogen peroxide, and the high-temperature DIW to the processing tub 61 so that the concentrations of the aqueous ammonia and the aqueous hydrogen peroxide in the processing tub 61 reach required concentration levels.

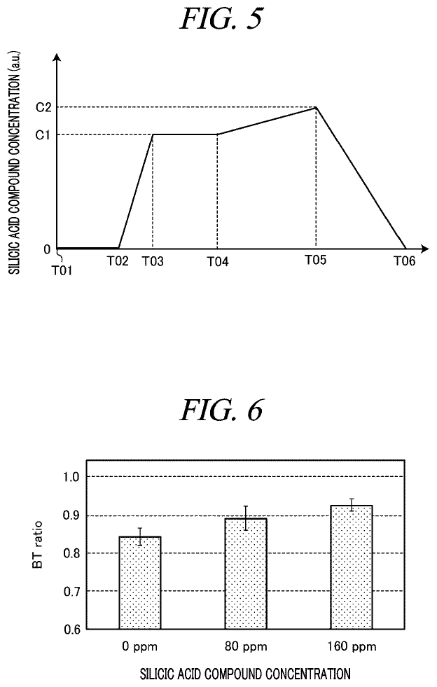

Next, the controller 9 controls the silicic acid supply 110 and the like to add the silicic acid compound to the SC1 in the processing tub 61 (process S103). As a result, as shown in FIG. 5, the concentration of the silicic acid compound in the processing tub 61 increases from a time T02 when the processing of the process S103 has begun. FIG. 5 shows an example of a variation of the concentration of the silicic acid compound in the processing tub 61 during the etching processing according to the present exemplary embodiment.

In FIG. 5, the processing liquid supplying processing of the process S102 described above is performed from a time T01 to the time T02. Also, in the example of FIG. 5, the concentration of the silicic acid compound is nearly zero at the time T01, and this concentration is maintained until the time T02.

Reference is made back to FIG. 4. Next, the controller 9 determines whether the concentration of the silicic acid compound in the processing tub 61 has reached a set concentration (e.g., a concentration C1 specified in FIG. 5) (process S104).

If the concentration of the silicic acid compound in the processing tub 61 has reached the set concentration (Yes in the process S104), the controller 9 assumes that the etching liquid L according to the exemplary embodiment has been produced, and carries the lot consisting of the multiple wafers W into the processing tub 61 (process S105).

For example, as shown in FIG. 5, if the concentration of the silicic acid compound in the processing tub 61 reaches the set concentration C1 at a time T03, the controller 9 terminates the processing of adding the silicic acid compound. As a result, the concentration of the silicic acid compound in the processing tub 61 is maintained at the set concentration C1.

On the other hand, if the concentration of the silicic acid compound in the processing tub 61 has not reached the preset concentration (No in the process S104), the processing returns back to the process S103.

Following the processing of the process S105, the controller 9 immerses the lot transferred to the processing tub 61 in the etching liquid L, and performs an etching processing on the multiple wafers W belonging to the lot (process S106).

As explained so far, in the present exemplary embodiment, the polysilicon film L2 located on the surface of the wafer W is etched by the etching liquid L, which is prepared by adding the silicic acid compound to the alkaline processing liquid (e.g., SC1).

As a result, the uniformity of the etching processing of the polysilicon film L2, for example, the uniformity between the etching amount of the polysilicon film L2 located at the bottom of the hole H shown in FIG. 2 and the etching amount of the polysilicon film L2 located at the opening of the hole H can be improved. The reason for this will be explained below.

In the etching processing of the polysilicon film L2 using the alkaline SC1, the aqueous hydrogen peroxide reacts in the SC1 as indicated by the following Chemical Expressions (1) and (2), thus generating oxygen molecules (O₂) and hydroxide ions (OH⁻).

H₂O₂+OH⁻⇔H₂O+OOH⁻ (1)

H₂O₂+OOH⁻→H₂O+O₂+OH⁻ (2)

Furthermore, in the etching processing using the SC1, the aqueous ammonia reacts in the SC1 as indicated by Chemical Expression (3) below, thus generating hydroxide ions (OH⁻).

NH₄OH→NH₄⁺+OH⁻ (3)

Then, the oxygen molecules O₂ generated in Chemical Expression (2) above react with the polysilicon film L2, thus generating silicon oxide SiO₂, as indicated by Chemical Expression (4) below.

Si+O₂→SiO₂ (4)

Furthermore, the hydroxide ions OH⁻ generated in the above Chemical Expressions (1) and (3) react with the silicon oxide SiO₂ generated in the above Chemical Expression (4) and the polysilicon film L2, thereby generating silicic acid Si(OH)₄, as represented by Chemical Expressions (5) and (6) below.

SiO₂+2OH⁻+2H⁺→Si(OH)₄ (5)

Si+2H₂O+2OH⁻→H₂+Si(OH)₄ (6)

As described above, the reactions of Chemical Expressions (1) through (6) are continued in the etching liquid L, gradually increasing the concentration of the silicic acid in the etching liquid L. As a result, with the progress of the etching processing, the reactions of Chemical Expressions (5) and (6) become less likely to proceed to the right.

As stated above, when etching the polysilicon film L2 with the alkaline processing liquid, the higher the concentration of the silicic acid is, the smaller the etching rate becomes. Further, although the present exemplary embodiment has been described for the example where the SC1 is used as the alkaline processing liquid, the same reactions occur with an alkaline processing liquid other than the SC1.

Furthermore, when etching the polysilicon film L2 located on the inner surface of the hole H with the alkaline processing liquid, as in the conventional technique, the opening of the hole H is relatively easily replenished with the processing liquid, which makes the aforementioned decrease in the etching rate less likely to occur.

On the other hand, it is more difficult for the fresh processing liquid to reach the bottom of the hole H than the opening, which makes an increase in the concentration of the silicic acid more likely to occur at the bottom of the hole H than at the opening thereof. As a result, the aforementioned decrease in the etching rate is more likely to occur at the bottom of the hole H.

For this region, in the conventional technique, a ratio of the etching rate at the bottom of the hole H to the etching rate at the opening of the hole H (also referred to as “BT (Bottom-to-Top) ratio” in the present disclosure) decreases, resulting in deterioration of the uniformity of the etching processing.

However, in the exemplary embodiment, the silicic acid compound is added to the alkaline processing liquid from the beginning of the etching processing. This makes the aforementioned decrease of the etching rate occur relatively easily at the opening of hole H as well from the beginning of the etching processing.

Therefore, in the exemplary embodiment, as compared to the conventional technique, a balance is achieved between a frequency of the etching reactions at the opening of hole H and a frequency of the etching reactions at the bottom of hole H.

Therefore, according to the present exemplary embodiment, the uniformity of the etching processing of the polysilicon film L2, for example, the uniformity between the etching amount of the polysilicon film L2 located at the bottom of the hole H and the etching amount of the polysilicon film L2 located at the opening of the hole H can be improved.

FIG. 6 shows a relationship between the concentration of the silicic acid compound added to the etching liquid L and the BT ratio. As shown in FIG. 6, when the concentration of the silicic acid compound is 0 ppm, that is, when no silicic acid compound is added to the initial alkaline processing liquid, the BT ratio is found to be significantly lower than an ideal value of 1.0.

On the other hand, when the etching processing is performed using the etching liquid L to which 80 ppm or 160 ppm of silicic acid compound is added from the beginning, as in the present exemplary embodiment, the BT ratio is found to approach the ideal value of 1.0, indicating that the uniformity of the etching processing has been improved.

As stated above, in the exemplary embodiment, by etching the wafer W with the etching liquid L in which the silicic acid compound is added to the alkaline processing liquid, the uniformity in the etching processing of the polysilicon film L2 can be improved.

Furthermore, in the exemplary embodiment, when generating the etching liquid L by adding the silicic acid compound to the alkaline processing liquid, the concentration of the silicic acid compound may be 400 ppm or less. This can further improve the uniformity in the etching processing of the polysilicon film L2.

Reference is made back to FIG. 4. In parallel with the etching processing of the process S106, the controller 9 controls the silicic acid supply 110 and so forth to add the silicic acid compound to the etching liquid L in the processing tub 61 (process S107).

For example, in the exemplary embodiment, the silicic acid compound may be added to the etching liquid L so that it passes through a calibration curve connecting the set concentration C1 at a start time T04 of the etching processing and a set concentration C2 at an end time T05 of the etching processing, as shown in FIG. 5.

Further, correlation data, including data on this calibration curve, representing a correlation between the concentration of the silicic acid compound in the etching liquid L in the processing tub 61 and the etching rate of the polysilicon film L2 is previously stored in the storage 10.

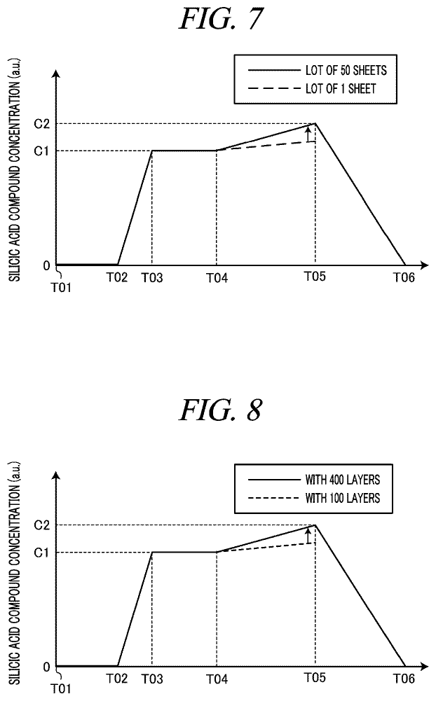

FIG. 7 and FIG. 8 are diagrams showing other example variations in the concentration of the silicic acid compound in the processing tub 61 during the etching processing according to the exemplary embodiment. As depicted in FIG. 7, when one lot is composed of one wafer W, the amount of the silicic acid dissolved in the etching liquid L during the etching processing is smaller than that in the case where one lot is composed of the 50 sheets of wafers W. Thus, a gradient in the increase of the concentration of the silicic acid compound is reduced.

As a result, when one lot is composed of one wafer W, there is a risk that the etching rate may significantly increase, especially in the latter half of the etching processing, as compared to the case where one lot is composed of the 50 sheets of wafers W.

Therefore, in the exemplary embodiment, the controller 9 checks in advance the composition of the lot to be processed, and when the lot to be processed is composed of a small number of wafers W, the controller 9 increases the amount of the silicic acid compound added in the process S107, as compared to a case where the lot is composed of a large number of wafers W.

This allows the etching processing to be performed under the same concentration profile of the silicic acid compound throughout the entire period of the etching processing, regardless of how many wafers are in the lot. Therefore, according to the exemplary embodiment, the etching processing can be performed under the uniform conditions across multiple lots.

Furthermore, when a 100-layer multilayer film is provided on the surface of the wafer W, the amount of the silicic acid dissolved in the etching liquid L during the etching processing becomes smaller than that in a case where a 400-layer multilayer film is provided on the surface of the wafer W, as shown in FIG. 8, resulting in a smaller gradient in the increase of the concentration of the silicic acid compound.

As a result, when the 100-layer multilayer film is provided on the surface of the wafer W, there is a risk that the etching rate may increase significantly, especially in the latter half of the etching processing, as compared to the case where the 400-layer multilayer film is provided on the surface of the wafer W.

In view of this, in the exemplary embodiment, the controller 9 checks in advance the composition of the lot to be processed. If the wafer W belonging to the lot to be processed is composed of a small number of layers, the controller 9 increases the amount of the silicic acid compound added in the process S107, as compared to the case where the wafer W is composed of a large number of layers.

As a result, the etching processing can be performed under the same concentration profile of the silicic acid compound throughout the entire period of the etching processing, regardless of how many layers the wafer W is composed of. Therefore, according to the exemplary embodiment, the etching processing can be performed under the uniform conditions in the multiple lots.

Reference is made back to FIG. 4. Following the processing of the processes S106 and S107 described above, the controller 9 determines whether a set processing time has elapsed (process S108).

If the set processing time has passed by (Yes in the process S108), the controller 9 assumes that the etching processing of the lot has been completed, and takes out the lot from the processing tub 61 (process S109) and terminates the series of processes of the control processing.

On the other hand, if the set processing time has not elapsed (No in the process S108), the controller 9 returns back to the processing of the processes S106 and S107.

Further, the controller 9 performs a rinsing processing, a cleaning processing, and a drying processing on the lot taken out from the processing tub 61, and then carries the lot from the lot processing module 6 to the carrier carry-in/out module 2.

In addition, referring to FIG. 5, starting from the time T05 when the etching processing of the one lot is completed, the above-described processing of the process S101, in which the used etching liquid L stored in the processing tub 61 is drained from the processing tub 61, is performed as a part of an etching processing of a next lot to be processed. As a result, the concentration of the silicic acid compound in the processing tub 61 decreases, as shown in FIG. 5.

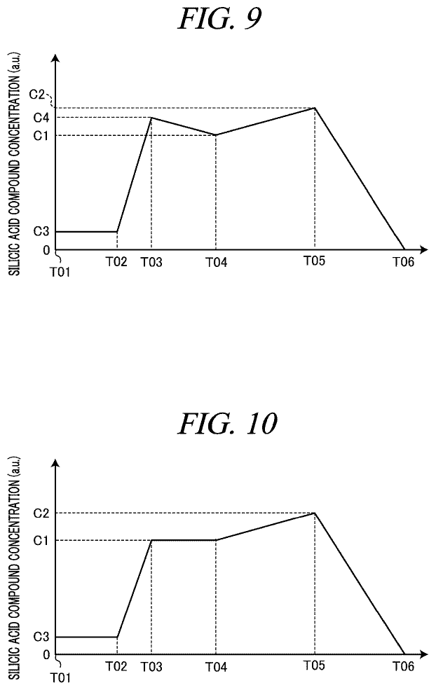

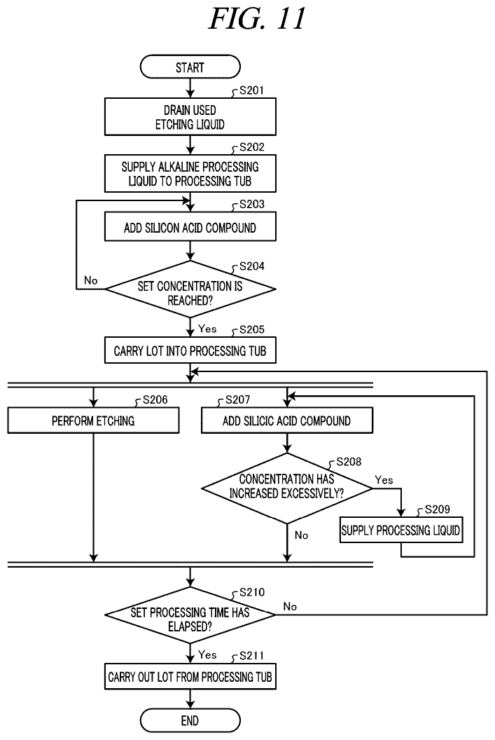

Here, if the used etching liquid L is not completely drained, the silicic acid compound may remain in the processing tub 61, and the concentration of the silicic acid compound may not be returned back to zero at the time T01 shown in FIG. 5. In this case, in the exemplary embodiment, a processing shown in FIG. 9 or FIG. 10 may be performed.

FIG. 9 and FIG. 10 are diagrams showing other example variations in the concentration of the silicic acid compound in the processing tub 61 during the etching processing according to the exemplary embodiment. In the example of FIG. 9, when the concentration of the silicic acid compound in the processing tub 61 is a concentration C3, which is higher than zero, at a time T01, the controller 9 performs the processing of the processes S102 and S103 described above, with the same supply amount and addition amount as those when the concentration of the silicic acid compound in the processing tub 61 is zero.

As a result, as shown in FIG. 9, at a time T03, the concentration of the silicic acid compound in the processing tub 61 becomes a concentration C4 higher than the set concentration C1. In this case, the controller 9 drains the etching liquid L from the etching liquid draining device 140 and replenishes the SC1 from the processing liquid supply 100, thereby reducing the concentration of the silicic acid compound in the processing tub 61.

This allows the concentration of the silicic acid compound in the processing tub 61 to become the set concentration C1 at a time T04 when the etching processing is begun.

Further, in the example of FIG. 10, when the concentration of the silicic acid compound in the processing tub 61 is the concentration C3, which is higher than zero, at a time T01, the controller 9 performs the processing of the process S102 described above, with the same supply amount as those when the concentration of the silicic acid compound in the processing tub 61 is zero.

Then, in the processing of the process S103, the controller 9 decreases the addition amount of the silicic acid compound, as compared to the case where the concentration of the silicic acid compound in the processing tub 61 is zero. This allows the concentration of the silicic acid compound in the processing tub 61 to become the set concentration C1 at a time T03 when the processing of the process S103 is ended.

Furthermore, in the exemplary embodiment, the alkaline processing liquid used as the source material of the etching liquid L may be diluted aqueous ammonia, SC1, NC2 (a mixture of an aqueous solution of choline and aqueous hydrogen peroxide), or TMAH (tetramethylammonium hydroxide). This allows for efficient etching of the polysilicon film L2 formed on the surface of the wafer W.

In addition, in the exemplary embodiment, the silicic acid compound used as the source material of the etching liquid L may contain at least one of silicic acid and silicate. As a result, the silicic acid compound can be easily dissolved in the alkaline processing liquid, making it possible to easily produce the etching liquid L.

Besides, in the exemplary embodiment, the controller 9 may adjust the etching time for the lot based on the concentration of the silicic acid compound in the processing tub 61. By way of example, if the concentration of the silicic acid compound in the processing tub 61 exhibits a higher profile than expected, the controller 9 may extend the etching time.

Also, if the concentration of the silicic acid compound in the processing tub 61 shows a lower profile than expected, the controller 9 may shorten the etching time.

In this way, by adjusting the etching time according to the concentration of the silicic acid compound in the processing tub 61, the etching processing can be performed uniformly across the multiple lots.

Furthermore, in the exemplary embodiment, the temperature of the etching liquid L when etching the lot may be in the range of 40° C. to 80° C. This enables efficient etching of the polysilicon film L2 formed on the surface of the wafer W.

In addition, in the exemplary embodiment, the concentration sensor 137 configured to measure the concentration of the silicic acid compound in the etching liquid L may be a microwave plasma atomic emission spectrometer, an inductively coupled plasma optical emission spectrometer, or an inductively coupled plasma mass spectrometer. With this configuration, the concentration of the silicic acid compound in the etching liquid L can be accurately measured.

Further, in the exemplary embodiment, if the controller 9 determines that the concentration of the silicic acid compound in the processing tub 61 will reach a set threshold value after etching a lot scheduled to be processed next, the controller 9 may replace the etching liquid L in the processing tub 61 before etching that next lot.

This suppresses the concentration of the silicic acid compound in the processing tub 61 from rising excessively when the next lot is etched, thus enabling the required etching processing to be carried out stably.

Moreover, in the exemplary embodiment, the controller 9 may control the operation of the processing liquid supply 100 so that the concentration of the alkaline processing liquid in the processing tub 61 falls within a set concentration range. By way of example, if the concentration of the processing liquid in the processing tub 61 exceeds the set concentration range, the controller 9 may drain the etching liquid L from the etching liquid draining device 140 and replenish the processing liquid with a lower concentration or HDIW from the processing liquid supply 100.

Furthermore, If the concentration of the processing liquid in the processing tub 61 falls below the set concentration range, the controller 9 may drain the etching liquid L from the etching liquid draining device 140 and replenish the processing liquid with a higher concentration from the processing liquid supply 100.

In this way, by stabilizing the concentration of the alkaline processing liquid in the processing tub 61 within the set concentration range, the required etching processing can be performed stably.

FIG. 11 is a flowchart showing another example sequence of the control processing performed by the substrate processing system 1 according to the exemplary embodiment.

In the control processing according to the example of FIG. 11, the controller 9 first controls the etching liquid draining device 140 and the like to drain the used etching liquid L stored in the processing tub 61 (process S201). The controller 9 then controls the processing liquid supply 100 and the like to supply the SC1, which is the alkaline processing liquid, to the processing tub 61 (process S202).

Next, the controller 9 controls the silicic acid supply 110 and the like to add the silicic acid compound to the SC1 in the processing tub 61 (process S203).

Next, the controller 9 determines whether the concentration of the silicic acid compound in the processing tub 61 has reached a set concentration (process S204). If the concentration of the silicic acid compound in the processing tub 61 has reached the set concentration (Yes in the process S204), the controller 9 carries the lot into the processing tub 61 (process S205).

On the other hand, if the concentration of the silicic acid compound in the processing tub 61 has not reached the set concentration (No in the process S204), the processing returns back to the process S203.

Following the process S205, the controller 9 immerses the lot carried into the processing tub 61 in the etching liquid L, thereby performing the etching processing on the multiple wafers W belonging to the lot (process S206). The processing of the processes S201 to S206 described so far are the same as the processing of the processes S101 to S106 described above, so a detailed description thereof will be omitted.

In parallel with the etching processing of the process S206, the controller 9 controls the silicic acid supply 110 and the like to add the silicic acid compound to the etching liquid L in the processing tub 61 (process S207).

Next, the controller 9 determines whether the concentration of the silicic acid compound in the processing tub 61 has risen excessively (process S208). If the concentration of the silicic acid compound in the processing tub 61 has increased excessively (Yes in the process S208), the controller 9 supplies an alkaline processing liquid to the processing tub 61 to reduce the concentration of the silicic acid compound (process S209), and returns to the processing of the process S207.

On the other hand, if the concentration of the silicic acid compound in the processing tub 61 has not increased excessively (No in the process S208), the controller 9 proceeds to a process S210.

Following the processing of the processes S206 and S208, the controller 9 determines whether a set processing time has elapsed (process S210). If the set processing time has passed by (Yes in the process S210), the controller 9 assumes that the etching processing of the lot has been completed, so the controller 9 carries out the lot from the processing tub 61 (process S211), which ends the series of processes of the control processing.

On the other hand, if the set processing time has not elapsed (No in the process S210), the controller 9 returns back to the processing of the processes S206 and S207

As described so far, in the example of FIG. 11, when the concentration of the silicic acid compound in the processing tub 61 reaches a set threshold value during the etching processing of a certain lot, at least a portion of the etching liquid L in the processing tub 61 may be replaced during the etching processing of that lot.

As a result, the concentration of the alkaline processing liquid in the processing tub 61 can be stabilized within a set concentration range, thereby enabling the required etching processing to be carried out stably.

A substrate processing method according to the exemplary embodiment includes a process of generating the etching liquid L (processes S102 and S103) and a process of performing etching (process S106). The process of generating the etching liquid L (processes S102 and S103) involves adding a silicic acid compound to an alkaline processing liquid to generate the etching liquid L. The process of performing the etching (process S106) includes etching the polysilicon film L2 formed on a substrate (wafer W) with the etching liquid L. As a consequence, the uniformity of the etching of the polysilicon film L2 formed on the wafer W can be improved.

Furthermore, in the substrate processing method according to the exemplary embodiment, the polysilicon film L2 is located on an inner surface of a recess (hole H) formed in a surface of the substrate (wafer W). In the process of performing the etching (process S106), at least a portion of the polysilicon film L2 located on the inner surface of the recess (hole H) is etched. As a result, the uniformity between an etching amount of the polysilicon film L2 located at the bottom of the hole H and an etching amount of the polysilicon film L2 located at the opening of the hole H can be improved.

Further, in the substrate processing method according to the exemplary embodiment, the silicic acid compound is colloidal silica. Therefore, the etching liquid L can be easily generated.

In the substrate processing method according to the exemplary embodiment, the silicic acid compound is at least one of sodium silicate, potassium silicate, and calcium silicate. Therefore, the etching liquid L can be easily generated.

Furthermore, in the substrate processing method according to the exemplary embodiment, the processing liquid is diluted aqueous ammonia, SC1, NC2, or TMAH. This enables efficient etching of the polysilicon film L2 formed on the surface of the wafer W.

Further, a substrate processing apparatus (substrate processing system 1) according to the exemplary embodiment includes the processing tub 61, the processing liquid supply 100, the silicic acid supply 110, the concentration measurer 136, the controller 9, and the storage 10. The processing tub 61 performs an etching processing by immersing a lot consisting of one or more substrates (wafers W) in the etching liquid L, which is generated by adding a silicic acid compound to an alkaline processing liquid. The processing liquid supply 100 supplies the processing liquid to the processing tub 61. The silicic acid supply 110 supplies the silicic acid compound to the processing tub 61. The concentration measurer 136 measures the concentration of the components of the etching liquid L stored in the processing tub 61. The controller 9 controls the individual components. The storage 10 stores correlation data representing a correlation between the concentration of the silicic acid compound in the etching liquid L in the processing tub 61 and the etching rate of the polysilicon film L2 formed on the substrate (wafer W). With this configuration, the uniformity of the etching processing of the polysilicon film L2 formed on the wafer W can be improved.

Furthermore, in the substrate processing apparatus (substrate processing system 1) according to the exemplary embodiment, the controller 9 adjusts the amount of the silicic acid compound supplied to the processing tub 61 based on the correlation data and the composition of the lot scheduled to be processed. As a result, the required etching processing can be stably performed.

In addition, in the substrate processing apparatus (substrate processing system 1) according to the exemplary embodiment, when it is determined that the concentration of the silicic acid compound in the etching liquid L in the processing tub 61 will reach a set threshold value after the etching processing of the lot scheduled to be processed, the controller 9 replaces at least a portion of the etching liquid L in the processing tub 61 before the etching processing of that lot. This suppresses the concentration of the silicic acid compound in the processing tub 61 from rising excessively when a next lot scheduled to be processed is etched. As a result, the required etching processing can be stably performed.

Furthermore, in the substrate processing apparatus (substrate processing system 1) according to the exemplary embodiment, the controller 9 supplies the silicic acid compound to the processing tub 61 during the etching processing of the lot. As a result, the etching processing can be performed under uniform conditions across multiple lots.

Besides, in the substrate processing apparatus (substrate processing system 1) according to the exemplary embodiment, when the concentration of the silicic acid compound in the etching liquid L in the processing tub 61 reaches a set threshold value during the etching processing of that lot, the controller 9 replaces at least a portion of the etching liquid L in the processing tub 61 during the etching processing of that lot. This enables the concentration of the alkaline processing liquid in the processing tub 61 to be stabilized within a set concentration range, so that the required etching processing can be carried out reliably.

Further, in the substrate processing apparatus (substrate processing system 1) according to the exemplary embodiment, the correlation data includes a calibration curve indicating the correlation between the concentration of the silicic acid compound in the etching liquid L in the processing tub 61 and the etching rate of the polysilicon film L2 formed on the substrate (wafer W). Therefore, the etching processing can be performed under the uniform conditions across the multiple lots.

Furthermore, in the substrate processing apparatus (substrate processing system 1) according to the exemplary embodiment, the controller 9 adjusts the time of the etching processing to be performed on the lot based on the concentration of the silicic acid compound in the processing tub 61 measured by the concentration measurer 136. This allows the etching processing to be performed under the uniform conditions across the multiple lots.

Moreover, in the substrate processing apparatus (substrate processing system 1) according to the exemplary embodiment, the concentration sensor 137 of the concentration measurer 136, which measures the concentration of the silicic acid compound in the etching liquid L in the processing tub 61, is a microwave plasma atomic emission spectrometer, an inductively coupled plasma optical emission spectrometer, or an inductively coupled plasma mass spectrometer. With this configuration, the concentration of the silicic acid compound in the etching liquid L can be measured with high precision.

Furthermore, in the substrate processing apparatus (substrate processing system 1) according to the exemplary embodiment, the processing liquid is diluted aqueous ammonia, SC1, NC2, or TMAH. This enables efficient etching of the polysilicon film L2 formed on the surface of the wafer W.

Also, in the substrate processing apparatus (substrate processing system 1) according to the exemplary embodiment, the controller 9 controls the operation of the processing liquid supply 100 so that the concentration of the processing liquid in the processing tub 61 falls within a set concentration range. As a result, the required etching processing can be stably performed.

Furthermore, in the substrate processing apparatus (substrate processing system 1) according to the exemplary embodiment, the temperature of the etching liquid L when etching the lot is in the range of 40° C. to 80° C. This allows for efficient etching of the polysilicon film L2 formed on the surface of the wafer W.

So far, the exemplary embodiment of the present disclosure has been described. However, it should be noted that the present disclosure is not limited to the above-described exemplary embodiment, and various modifications may be made without departing from the spirit of the present disclosure. By way of example, although the above exemplary embodiment has been described for the case where the device structure formed on the wafer W is like the example shown in FIG. 2, the device structure formed on the wafer W is not limited thereto.

Furthermore, in the above-described exemplary embodiment, the etching processing of the wafers W by the etching liquid L is implemented by a so-called batch processing. However, the present disclosure is not limited thereto. The etching processing of the wafers W by the etching liquid L may be implemented by a so-called single-wafer processing. This also contributes to the improvement of the uniformity of the etching processing of the polysilicon film L2 formed on the wafer W.

It should be noted that the above-described exemplary embodiment is illustrative in all aspects and is not anyway limiting. In fact, the above-described exemplary embodiment can be embodied in various forms. The above-described exemplary embodiment may be omitted, replaced and modified in various ways without departing from the scope and the spirit of claims.

According to the exemplary embodiment, it is possible to improve the uniformity of the etching processing of the polysilicon film formed on the substrate. However, this effect is not meant to be limiting and any of the effects mentioned in the present disclosure may be achieved.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim

1. A substrate processing method, comprising:
generating an etching liquid by adding a silicic acid compound to an alkaline processing liquid; and
etching a polysilicon film formed on a substrate with the etching liquid.

2. The substrate processing method of claim 1,
wherein the polysilicon film is provided on an inner surface of a recess formed in a surface of the substrate, and
the etching of the polysilicon film includes etching at least a portion of the polysilicon film provided on the inner surface of the recess.

3. The substrate processing method of claim 1, wherein a concentration of silicic acid in the alkaline processing liquid is between 80 ppm and 160 ppm.

4. The substrate processing method of claim 1,
wherein the silicic acid compound is colloidal silica.

5. The substrate processing method of claim 1,
wherein the silicic acid compound is at least one of sodium silicate, potassium silicate, or calcium silicate.

6. The substrate processing method of claim 1,
wherein the processing liquid is diluted aqueous ammonia, SC1 (a mixture of aqueous ammonia and aqueous hydrogen peroxide), NC2 (a mixture of an aqueous solution of choline and an aqueous hydrogen peroxide), or TMAH (tetramethylammonium hydroxide).

7. The substrate processing method of claim 1, wherein a temperature of the etching liquid when performing the etching processing of the lot is in a range of 40° C. to 80° C.

8. A substrate processing apparatus, comprising:
a processing tub in which an etching processing is performed by immersing a lot, which includes one or more substrates, in an etching liquid prepared by adding a silicic acid compound to an alkaline processing liquid;
a processing liquid supply configured to supply the processing liquid to the processing tub;
a silicic acid supply configured to supply the silicic acid compound to the processing tub;
a concentration measurement circuit configured to measure a concentration of a component of the etching liquid stored in the processing tub;
controller circuitry configured to control individual components; and
a storage circuit configured to store correlation data representing a correlation between a concentration of the silicic acid compound in the etching liquid in the processing tub and an etching rate of a polysilicon film formed on the substrate.

9. The substrate processing apparatus of claim 8,
wherein the controller circuitry adjusts an amount of the silicic acid compound supplied to the processing tub based on the correlation data and a composition of the lot scheduled to be subjected to an etching processing.

10. The substrate processing apparatus of claim 9,
wherein the controller circuitry controls supply of the silicic acid compound to the processing tub before the etching processing of the lot scheduled to be subjected to the etching processing.

11. The substrate processing apparatus of claim 10,
wherein the controller circuitry controls replacement of, when it is determined that the concentration of the silicic acid compound in the etching liquid in the processing tub reaches a set threshold value after the etching processing of the lot scheduled to be subjected to the etching processing, at least a portion of the etching liquid in the processing tub before the etching processing of the lot.

12. The substrate processing apparatus of claim 9,
wherein the controller circuitry controls supply of the silicic acid compound to the processing tub during the etching processing of the lot.

13. The substrate processing apparatus of claim 12,
wherein the controller circuitry controls replacement of, when the concentration of the silicic acid compound in the etching liquid in the processing tub reaches a set threshold value during the etching processing of the lot, at least a portion of the etching liquid in the processing tub during the etching processing of the lot.

14. The substrate processing apparatus of claim 9,
wherein the correlation data include a calibration curve representing the correlation between the concentration of the silicic acid compound in the etching liquid in the processing tub and the etching rate of the polysilicon film formed on the substrate.

15. The substrate processing apparatus of claim 9,
wherein the controller circuitry adjusts a time of the etching processing to be performed on the lot, based on the concentration of the silicic acid compound in the processing tub, which is measured by the concentration measurement circuit.

16. The substrate processing apparatus of claim 9,
wherein a concentration sensor of the concentration measurement circuit, which is configured to measure the concentration of the silicic acid compound in the etching liquid in the processing tub, is a microwave plasma atomic emission spectrometer, an inductively coupled plasma optical emission spectrometer, or an inductively coupled plasma mass spectrometer.

17. The substrate processing apparatus of claim 9,
wherein the processing liquid is diluted aqueous ammonia, SC1 (a mixture of aqueous ammonia and aqueous hydrogen peroxide), NC2 (a mixture of an aqueous solution of choline and an aqueous hydrogen peroxide), or TMAH (tetramethylammonium hydroxide).

18. The substrate processing apparatus of claim 17,
wherein the controller circuitry controls an operation of the processing liquid supply so that a concentration of the processing liquid in the processing tub falls within a set concentration range.

19. The substrate processing apparatus of claim 9,
wherein a temperature of the etching liquid when performing the etching processing of the lot is in a range of 40° C. to 80° C.

20. The substrate processing apparatus according to claim 8, wherein a concentration of silicic acid in the alkaline processing liquid is between 80 ppm and 160 ppm.
